(19) United States
(12) Patent Application Publication
(10) Pub. No.: US 2016/0013794 A1
(43) Pub. Date: Jan. 14, 2016

(54) LOW POWER DIVIDE-BY-SEVEN DIVIDER

(71) Applicant: QUALCOMM Incorporated, San Diego, CA (US)

(72) Inventors: Wenjun SU, San Diego, CA (US); Le ZHANG, Shanghai (CN); Chulkyu LEE, San Diego, CA (US)

(21) Appl. No.: 14/328,671

(22) Filed: Jul. 10, 2014

(51) Int. Cl. H03K 21/00

(52) U.S. Cl. CPC H03K 21/00

(57) ABSTRACT

A divide-by-seven divider includes a first module clocked with a clock input, and a second module coupled to the first module and clocked with an output of the first module. The first and second modules are configured to divide the clock input by seven and to output the divided clock input. The first module may be configured to store a count between 0 and 3 in a count cycle. The divide-by-seven divider may further include a feedback module coupled between the first module and the second module that is configured to cause the first module to skip one count in the count between 0 and 3 once every other count cycle. Specifically, the first module may be configured to store incrementally the count “00,” “10,” “11,” and “01” in a count cycle and to skip the count “01” every other count cycle based on input from the feedback module.

### BACKGROUND

1. Field

The present disclosure relates generally to a circuit, and more particularly, to a low power divide-by-seven divider circuit.

2. Background

High speed divide-by-seven dividers may be used in transmitters/receivers of user equipment (UE) to support wireless communications. Existing divide-by-seven dividers have a relatively high power consumption. Divide-by-seven dividers with a lower power consumption than existing divide-by-seven dividers are needed to reduce UE power consumption in wireless communications.

### SUMMARY

In an aspect of the disclosure, a divide-by-seven divider apparatus includes a first module clocked with a clock input, and a second module coupled to the first module and clocked with an output of the first module. The first module and the second module are configured to divide the clock input by seven and to output the divided clock input. In particular, the first module may be configured to store a count between 0 and 3 in a count cycle. The divide-by-seven divider may further include a feedback module coupled between the first module and the second module that is configured to cause the first module to skip one count in the count between 0 and 3 once every other count cycle. Specifically, the first module may be configured to store incrementally the count “00,” “10,” “11,” and “01” in a count cycle and to skip the count “01” every other count cycle based on input from the feedback module.

In an aspect of the disclosure, a method of operating a divide-by-seven divider apparatus and a divide-by-seven divider apparatus are provided. The divide-by-seven divider apparatus stores a count between 0 and 3 in a count cycle within a first module. The first module is clocked with a clock input. The divide-by-seven divider apparatus clocks a second module with an output of the first module. The second module is coupled to the first module. The divide-by-seven divider apparatus causes, by a feedback module, the first module to skip one count in the count between 0 and 3 once every other count cycle. The feedback module is coupled between the first module and the second module. The first module, the second module, and the feedback module are configured to divide the clock input by seven. The divide-by-seven divider apparatus outputs the divided clock input.

### BRIEF DESCRIPTION OF THE DRAWINGS

FIG. 1 is a diagram illustrating a serializer/deserializer with divide-by-seven dividers.

FIG. 2 is a circuit diagram of a first exemplary divide-by-seven divider.

FIG. 3 illustrates timing diagrams for the first exemplary divide-by-seven divider.

FIG. 4 is a circuit diagram of a second exemplary divide-by-seven divider.

FIG. 5 illustrates timing diagrams for the second exemplary divide-by-seven divider.

FIG. 6 is a flow chart illustrating a method of operation of the exemplary divide-by-seven dividers.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts. Apparatuses and methods will be described in the following detailed description and may be illustrated in the accompanying drawings by various blocks, modules, components, circuits, steps, processes, algorithms, elements, etc.

High speed divide-by-seven dividers may be used in transmitters/receivers of UE to support wireless communications. Divide-by-seven dividers may include data/delay (D) flip-flops (DFFs). Such DFFs may each be clocked at full speed by an input clock, which results in a higher power consumption by each of the DFFs. Further, divide-by-seven dividers may include a feedback path from the most divided-down logic (lowest speed) to the first stage input (highest speed). The feedback signal in such a feedback path needs to match the input clock speed, resulting in a higher power consumption of logic gates in the feedback path. Accordingly, existing divide-by-seven dividers have a relatively high power consumption. Exemplary divide-by-seven dividers are provided infra with a lower power consumption than existing divide-by-seven dividers.

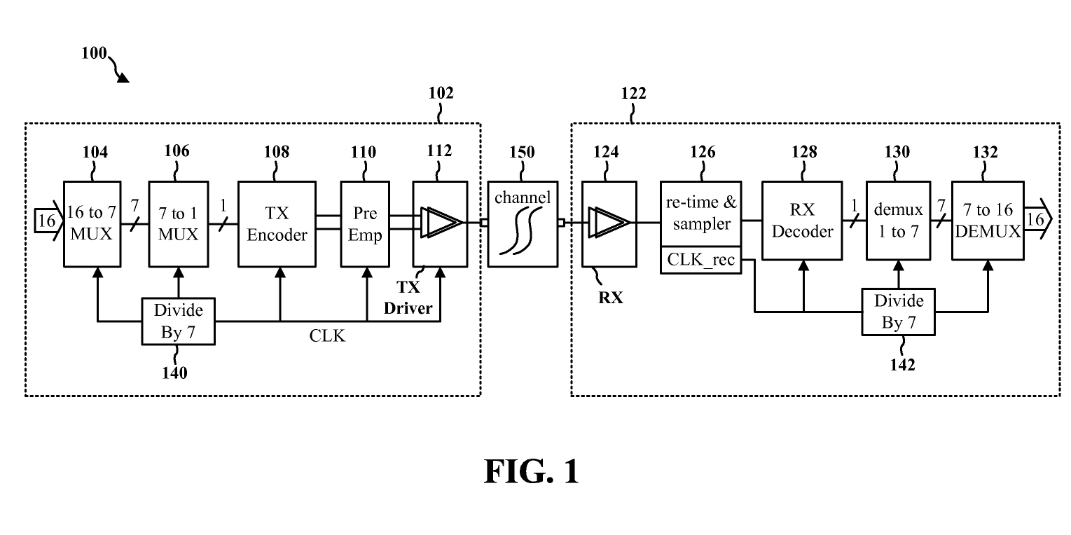

FIG. 1 is a diagram 100 illustrating a serializer/deserializer (SerDes) with divide-by-seven dividers 140, 142. In the serializer 102 of the SerDes, a 16-to-7 multiplexer 104 receives a 16-bit parallel data input. The 16-to-7 multiplexer 104 selects seven of the received bits at a time and outputs a 7-bit parallel data output to a 7-to-1 multiplexer 106. The 7-to-1 multiplexer 106 selects one of the received bits at a time and outputs a 1-bit serial data output to a transmit (TX) encoder 108 that encodes the received data for transmission. The TX encoder 108 provides the encoded data to a preemphasis/equalization block 110 that employs a preemphasis filter/equalization to improve the signal for subsequent transmission. After processing, the preemphasis/equalization block 110 outputs the encoded data to a TX driver 112 for transmission on a transmission line/channel 150. In the deserializer 122, a receiver (RX) 124 receives an encoded data input from the transmission line/channel 150, and provides the received input to a re-time and sampler block 126. The re-time and sampler block 126 generates a clock signal in a serial clock recovery technique (e.g., a process known as clock and data recovery (CDR)). The re-time and sampler block 126 provides the recovered clock and the encoded data to an RX decoder 128. The RX decoder 128 decodes the received encoded data and provides a 1-bit serial data output to a 1-to-7 demultiplexer 130. The 1-to-7 demultiplexer 130 receives the 1-bit serial data input and provides a 7-bit parallel data output to a 7-to-16 demultiplexer 132. The 7-to-16 demultiplexer 132 receives the 7-bit parallel data input and provides a 16-bit parallel data output.

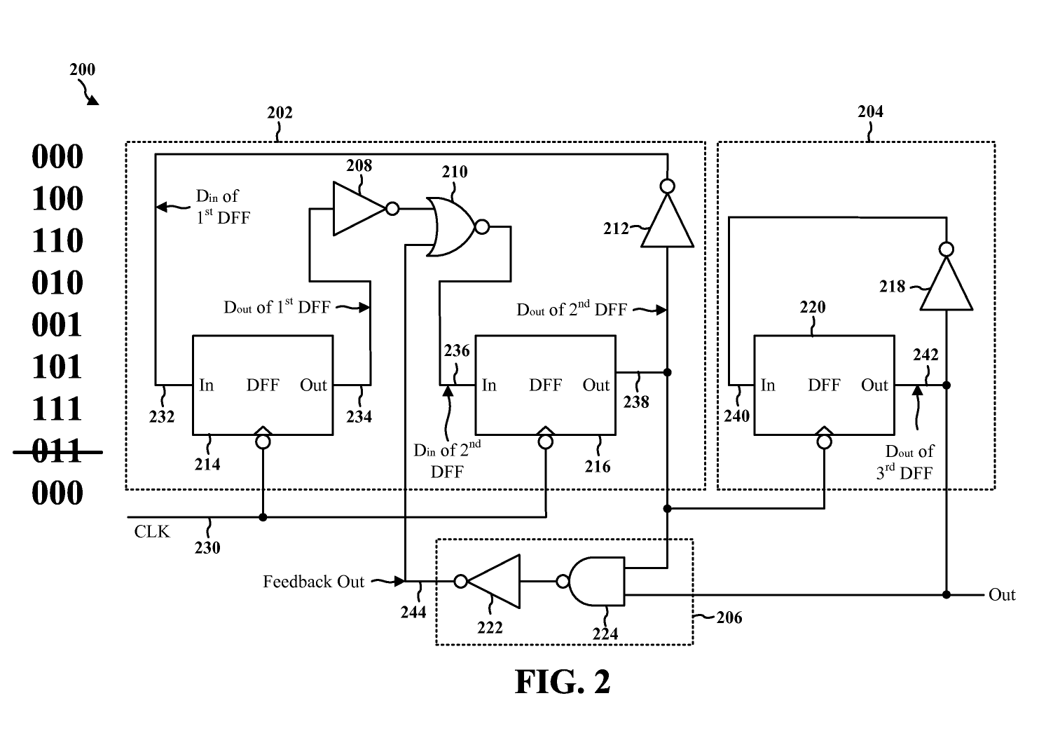

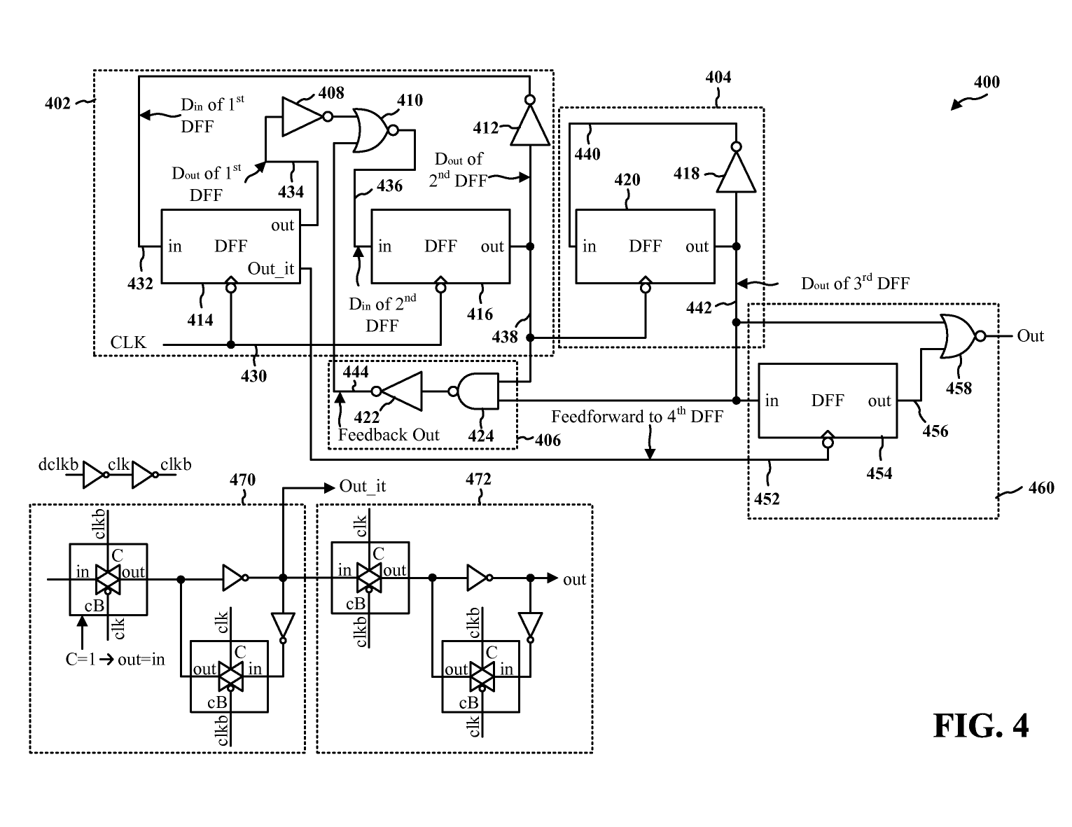

The TX encoder 108, the preemphasis/equalizer block 110, the TX driver 112, and the RX Decoder 128 each receive a clock input. Divide-by-seven dividers 140 and 142 also receive the clock input. The divide-by-seven dividers 140, 142 divide the received clock input by seven and provide a divided-by-seven clock input to the multiplexers/demultiplexers of the SerDes. Specifically, the divide-by-seven divider 140 receives a clock input, divides the received clock by seven (i.e., the period is seven times larger), and provides the divided-by-seven clock to the 16-to-7 multiplexer 104 and the 7-to-1 multiplexer 106. In addition, the divide-by-seven divider 142 receives a clock input from the re-time and sampler block 126, divides the received clock by seven, and provides the divided-by-seven clock to the 1-to-7 demultiplexer 130 and the 7-to-16 demultiplexer 132. Each of the divide-by-seven dividers 140 and 142 may be the divide-by-seven divider as provided infra in relation to FIG. 2 or the divide-by-seven divider as provided infra in relation to FIG. 4.

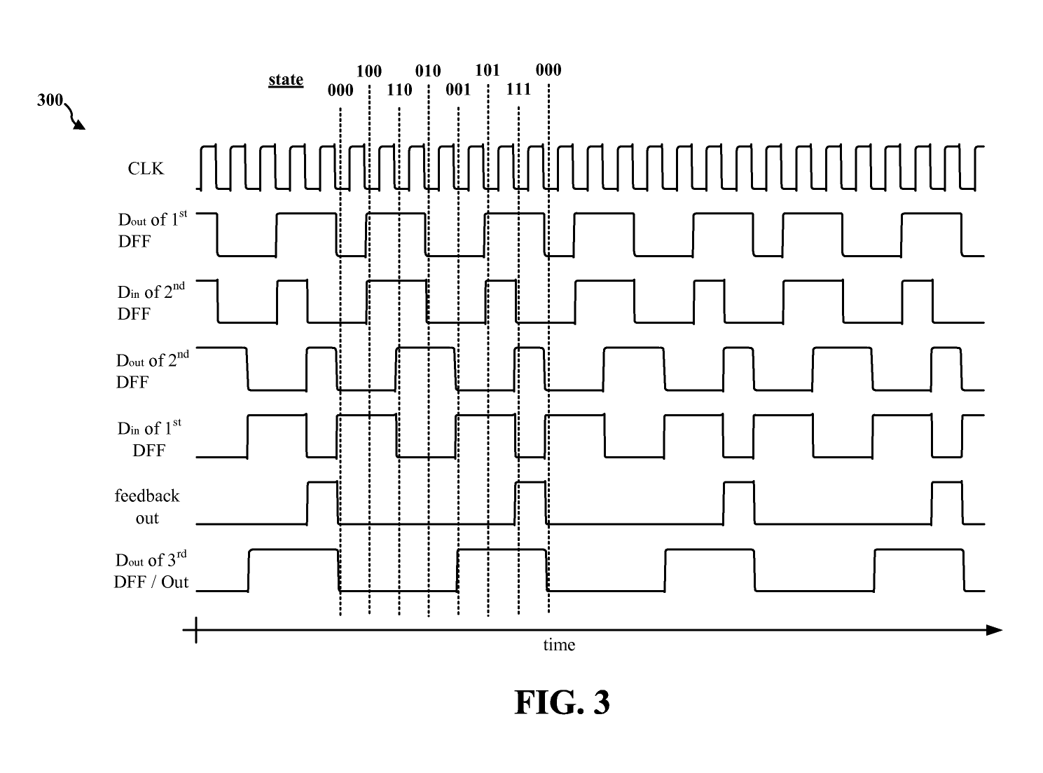

FIG. 2 is a circuit diagram 200 of a first exemplary divide-by-seven divider. FIG. 3 illustrates timing diagrams 300 for the first exemplary divide-by-seven divider of FIG. 2. The divide-by-seven divider includes a first module 202, a second module 204, and a feedback module 206. The first module 202 is clocked with a clock input 230. The second module 204 is coupled to an output 238 of the first module 202 and is clocked with the output 238 of the first module 202. The first module 202 includes a first DFF 214 and a second DFF 216. The second module 204 includes a third DFF 220. The output 238 of the first module 202 and the second DFF 216 (Dₒᵤₜ of the 2^{nd} DFF) is coupled to an input 232 of the first DFF 214 (Dᵢₙ of the 1^{st} DFF) through an inverter 212. An output 234 of the first DFF 214 (Dₒᵤₜ of the 1^{st} DFF) is coupled to an input 236 of the second DFF 216 (Dᵢₙ of the 2^{nd} DFF) through an inverter 208 and a NOR gate 210. The feedback module 206 receives two inputs, the output 238 of the first module 202/the second DFF 216 and an output 242 of the second module 204/the third DFF 220 (Dₒᵤₜ of the 3^{rd} DFF). The output 242 of the second module 204/the third DFF 220 is an output (Out) of the divide-by-seven divider. The feedback module 206 provides an AND function and includes a NAND gate 224 that receives the two inputs, and an inverter 222 coupled to an output of the NAND gate 224. An output 244 of the inverter 222 (feedback out) is input to the NOR gate 210. In the second module 204, the output 242 of the second module 204/third DFF 220 is coupled to an input 240 of the second module 204/third DFF 220 through an inverter 218.

Each of the DFFs may include a master latch and a slave latch. On a rising edge of the clock, the master latch may store an input bit. On a falling edge of the clock, the master latch may output the stored bit to the slave latch and the slave latch may store the bit inputted by the master latch. The bit stored in the slave latch is outputted by the DFF.

A method of operation of the illustrated divide-by-seven divider will now be described. Assume the first DFF 214, the second DFF 216, and the third DFF 220 are in state 000 in which each are outputting a 0. While in state 000, the first DFF 214, the second DFF 216, and the third DFF 220 receive as inputs 1, 0, and 1, respectively. In a next clock transition (rise and fall of the clock), the first DFF 214, the second DFF 216, and the third DFF 220 are in state 100 in which the first DFF 214 is outputting a 1, the second DFF 216 is outputting a 0, and the third DFF 220 is outputting a 0. While in state 100, the first DFF 214, the second DFF 216, and the third DFF 220 receive as inputs 1, 1, and 1, respectively. In a next clock transition, the first DFF 214, the second DFF 216, and the third DFF 220 are in state 110 in which the first DFF 214 is outputting a 1, the second DFF 216 is outputting a 1, and the third DFF 220 is outputting a 0. While in state 110, the first DFF 214, the second DFF 216, and the third DFF 220 receive as inputs 0, 1, and 1, respectively. In a next clock transition, the first DFF 214, the second DFF 216, and the third DFF 220 are in state 010 in which the first DFF 214 is outputting a 0, the second DFF 216 is outputting a 1, and the third DFF 220 is outputting a 0. While in state 010, the first DFF 214, the second DFF 216, and the third DFF 220 receive as inputs 0, 0, and 1, respectively. In a next clock transition, the first DFF 214, the second DFF 216, and the third DFF 220 are in state 001 in which the first DFF 214 is outputting a 0, the second DFF 216 is outputting a 0, and the third DFF 220 is outputting a 1. The output 242 of the third DFF 220 changed from a 0 to a 1 because the output 238 of the first module 202/second DFF 216 changed from a 1 to a 0, and therefore the bit 1 stored in the master latch of the third DFF 220 was moved to the slave latch of the third DFF 220. While in state 001, the first DFF 214, the second DFF 216, and the third DFF 220 receive as inputs 1, 0, and 0, respectively. In a next clock transition, the first DFF 214, the second DFF 216, and the third DFF 220 are in state 101 in which the first DFF 214 is outputting a 1, the second DFF 216 is outputting a 0, and the third DFF 220 is outputting a 1. While in state 101, the first DFF 214, the second DFF 216, and the third DFF 220 receive as inputs 1, 1, and 0, respectively. In a next clock transition, the first DFF 214, the second DFF 216, and the third DFF 220 are in state 111 in which the first DFF 214 is outputting a 1, the second DFF 216 is outputting a 1, and the third DFF 220 is outputting a 1. While in state 111, the first DFF 214, the second DFF 216, and the third DFF 220 receive as inputs 0, 0, and 0, respectively. In a next clock transition, the first DFF 214, the second DFF 216, and the third DFF 220 return to state 000. Specifically, in the next clock transition, the first DFF 214, the second DFF 216, and the third DFF 220 are in state 000 in which the first DFF 214 is outputting a 0, the second DFF 216 is outputting a 0, and the third DFF 220 is outputting a 0. The output 242 of the third DFF 220 changed from a 1 to a 0 because the output 238 of the first module 202/second DFF 216 changed from a 1 to a 0, and therefore the bit 0 stored in the master latch of the third DFF 220 was moved to the slave latch of the third DFF 220.

Referring to when the first DFF 214, the second DFF 216, and the third DFF 220 are in state 111, both of the inputs of the feedback module 206 are 1, thus providing a feedback out signal of a 1. The feedback out signal of a 1 forces the input 236 of the second DFF 216 to a 0. Thus, the first DFF 214, the second DFF 216, and the third DFF 220 receive as inputs 0, 0, and 0, respectively, rather than inputs 0, 1, and 0, respectively. With inputs 0, 1, and 0, respectively, at the first DFF 214, the second DFF 216, and the third DFF 220, the next state would be 011. However, because the input 236 of the second DFF 216 is forced to a 0, in the next clock transition, the first DFF 214, the second DFF 216, and the third DFF 220 change to state 000 rather than 011. Accordingly, in state 111, the feedback module 206 forces the divide-by-seven divider to skip the state 011 and return/reset to the next state 000 on the next clock transition. By skipping the state 011, the output 242 has one period for every seven clock cycles, with an output of a 0 for 4/7 of the period, and an output of a 1 for 3/7 of the period, providing approximately a 43% duty cycle, or roughly a 40% duty cycle.

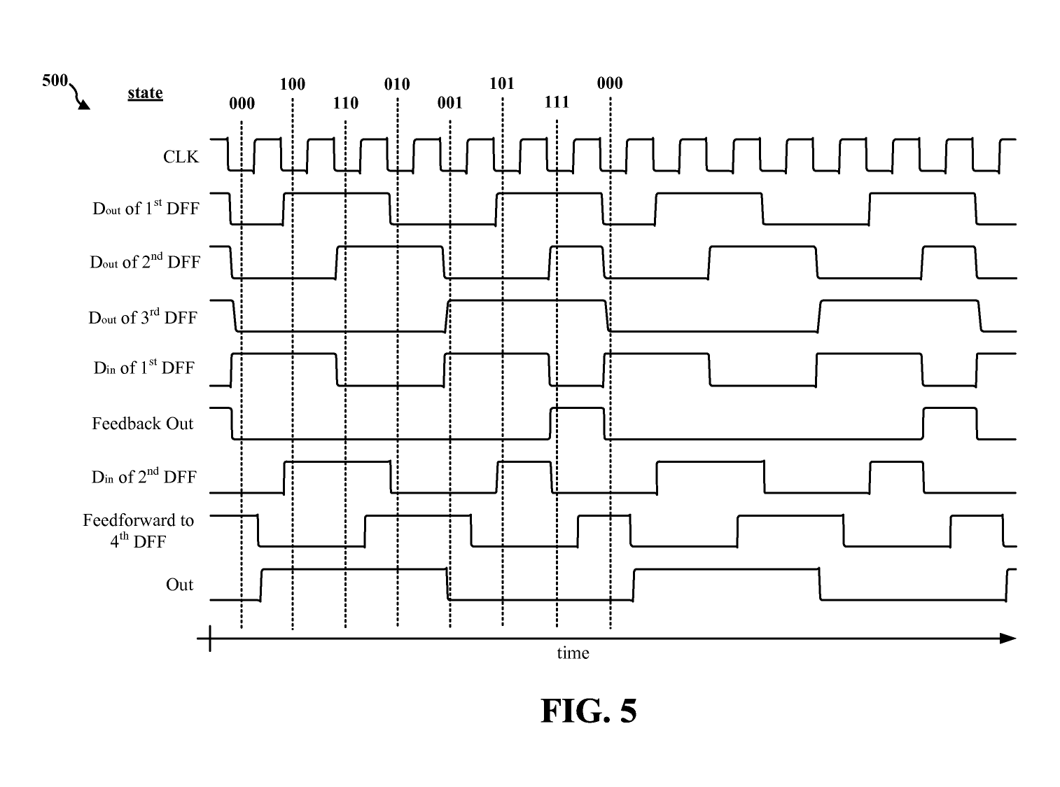

FIG. 4 is a circuit diagram 400 of a second exemplary divide-by-seven divider. FIG. 5 illustrates timing diagrams 500 for the second exemplary divide-by-seven divider of FIG. 4. The second exemplary divide-by-seven divider includes a first module 402, a second module 404, a feedback module 406, and a duty cycle adjustment module 460. The first module 402 is clocked with a clock input 430. The second module 404 is coupled to an output 438 of the first module 402 and is clocked with the output 438 of the first module 402. The first module 402 includes a first DFF 414 and a second DFF 416. The second module 404 includes a third DFF 420. The output 438 of the first module 402 and the second DFF 416 (Dₒᵤₜ of the 2^{nd} DFF) is coupled to an input 432 of the first DFF 414 (Dᵢₙ of the 1^{st} DFF) through an inverter 412. An output 434 of the first DFF 414 (Dₒᵤₜ of the 1^{st} DFF) is coupled to an input 436 of the second DFF 416 (Dᵢₙ of the 2^{nd} DFF) through an inverter 408 and a NOR gate 410. The feedback module 406 receives two inputs, the output 438 of the first module 402/the second DFF 416 and an output 442 of the second module 404/the third DFF 420 (Dₒᵤₜ of the 3^{rd} DFF). The feedback module 406 provides an AND function and includes a NAND gate 424 that receives the two inputs, and an inverter 422 coupled to an output of the NAND gate 424. An output 444 of the inverter 422 (feedback out) is input to the NOR gate 410. In the second module 404, the output 442 of the second module 404/third DFF 420 is coupled to an input 440 of the second module 404/third DFF 420 through an inverter 418. The output 442 of the second module 404/the third DFF 420 is input to the duty cycle adjustment module 460. The duty cycle adjustment module 460 includes a fourth DFF 454 and a NOR gate 458. The output 442 of the second module 404 / the third DFF 420 is input to both the fourth DFF 454 and the NOR gate 458. An output 456 of the fourth DFF 454 is also input to the NOR gate 458. The fourth DFF 454 is clocked by the output (Out it) 454 (feedforward to 4^{th} DFF) of the master latch 470 of the first DFF 414.

Each of the DFFs may include a master latch 470 and a slave latch 472. On a rising edge of the clock, the master latch 470 may store an input bit. On a falling edge of the clock, the master latch 470 may output the stored bit to the slave latch 472 and the slave latch 472 may store the bit inputted by the master latch 470. The bit stored in the slave latch 472 is outputted by the DFF.

A method of operation of the illustrated second divide-by-seven divider will now be described. The operation with respect to the first module 402, the second module 404, and the feedback module 406 is as described with respect to the first module 202, the second module 204, and the feedback module 206 of FIG. 2. At state 000, assume the fourth DFF 454 is storing a 0 (in the master latch), the feedforward 452 is high, and the output of the fourth DFF 460 is a 1 (the slave latch is storing a 1). The output 442 of the second module 404/the third DFF 420 is 0. Accordingly, the output (Out) of the NOR gate 458 is a 0. While in state 000, the first DFF 414 receives an input 1. On the next rise of the CLK, a 1 is stored in the master latch of the first DFF 414, and the feedforward provides a low signal to the fourth DFF 454. Accordingly, the fourth DFF 454 then outputs a 0, which causes the output (Out) to go high. The feedforward stays low until state 110 when the first DFF 214 receives input 0. On the next rise of the CLK, a 0 is stored in the master latch of the first DFF 414, and the feedforward provides a high signal to the fourth DFF 454. At state 001, the output 442 of the second module 404/the third DFF 420 is 1. Accordingly, the output (Out) goes low. While in state 001, the first DFF 414 receives an input 1. On the next rise of the CLK, a 1 is stored in the master latch of the first DFF 414, and the feedforward provides a low signal to the fourth DFF 454. Accordingly, the fourth DFF 454 then outputs a 1. The feedforward stays low until state 111 when the first DFF 214 receives input 0. On the next rise of the CLK, a 0 is stored in the master latch of the first DFF 414, and the feedforward provides a high signal to the fourth DFF 454. At state 000, the output 442 of the second module 404/the third DFF 420 is 0, but the output of the fourth DFF 454 is a 1, so the output (Out) stays low. However, while in state 000, the first DFF 414 receives an input 1. On the next rise of the CLK, a 1 is stored in the master latch of the first DFF 414, and the feedforward provides a low signal to the fourth DFF 454. Accordingly, the fourth DFF 454 then outputs a 0, which then causes the output (Out) to go high.

As shown in FIG. 5, the output (Out) of the divide-by-seven divider has one period for every seven clock cycles, with an output of a 0 for 3.5 of 7 CLK periods, and an output of a 1 for 3.5 of 7 CLK periods, providing approximately a 50% duty cycle. Accordingly, the duty cycle adjustment module 460 of FIG. 4 allows the divide-by-seven divider to provide a 50% duty cycle as opposed to roughly a 40% duty cycle of the divide-by-seven divider of FIG. 2.

Referring again to FIG. 2 and FIG. 4, a divide-by-seven divider includes a first module 202/402 clocked with a clock input CLK. The divide-by-seven divider further includes a second module 204/404 coupled to the first module 202/402 and clocked with an output 238/438 of the first module 202/402. The first module 202/402 and the second module 204/404 are configured to divide the clock input CLK by seven and to output the divided clock input. The first module 202/402 is configured to store a count between 0 and 3 in a count cycle. The divide-by-seven divider further includes a feedback module 206/406 coupled between the first module 202/402 and the second module 204/404. The feedback module 206/406 is configured to cause the first module 202/402 to skip one count in the count between 0 and 3 once every other count cycle. Specifically, the first module 202/402 is configured to store incrementally the count “00,” “10,” “11,” and “01” in a count cycle and to skip the count “01” every other count cycle based on input from the feedback module 206/406. The first module 202/402 includes a first stage 214/414 and a second stage 216/416. The first stage 214/414 has a first stage input 232/432 and a first stage output 234/434. The second stage 216/416 has a second stage input 236/436 and a second stage output 238/438. The second stage output 238/438 is coupled to the first stage input 232/432. The first stage output 234/434 is coupled to the second stage input 236/436. The second module 204/404 includes a third stage 220/420. The third stage 220/420 has a third stage input 240/440 and a third stage output 242/442. The third stage 220/420 is clocked by the second stage output 238/438. The third stage output 242/442 is coupled to the third stage input 240/440.

The feedback module 206/406 has a feedback module input 238, 242/438, 442 and a feedback module output 244/444. The feedback module input 238, 242/438, 442 is coupled to the third stage output 242/442 and the second stage output 238/438. The feedback module output 244/444 is coupled to the second stage input 236/436. The first stage 214/414 is a first DFF, the second stage 216/416 is a second DFF, and the third stage 220/420 is a third DFF.

The first module 202/402 may include a first inverter 208/408 coupled to the first stage output 234/434, a NOR gate 210/410 coupled between the first inverter 208/408 and the second stage input 236/436, and a second inverter 212/412 coupled between the second stage output 238/438 and the first stage input 232/432. Alternatively, the first module may include other logic gates that perform similar functions as the logic gates shown in FIG. 2 and FIG. 4. The second module 204/404 may further include a third inverter 218/418 coupled between the third stage output 242/442 and the third stage input 240/440. The feedback module 206/406 may include a NAND gate 224/424 receiving inputs from the second stage output 238/438 and the third stage output 242/442, and a fourth inverter 222/422 coupled to an output of the NAND gate 224/424. The feedback module 206/406 may include other logic gates that perform similar functions (e.g., an AND function) as the logic gates shown in FIG. 2 and FIG. 4. An output 244/444 of the fourth inverter 222/422 is coupled to an input of the NOR gate 210/410.

As shown in FIG. 2, an output (Out) of the divide-by-seven divider is the third stage output 242 and, as discussed supra, the divide-by-seven divider of FIG. 2 has roughly/approximately a 40% duty cycle. As shown in FIG. 4, the divide-by-seven divider includes a duty cycle adjustment module 460 that includes a fourth stage 454. The fourth stage 454 has a fourth stage input 442 and a fourth stage output 456. The first stage 414 has a first stage second output 452. The first stage second output 452 is a value stored in a master latch 470 of the first stage 414. The fourth stage 454 is clocked by the first stage second output 452. The third stage output 442 is coupled to the fourth stage input 442. The third stage output 442 and the fourth stage output 456 are coupled to an output (Out) of the divide-by-seven divider. Specifically, the third stage output 442 and the fourth stage output 456 are coupled to an input of a NOR gate 458. An output of the NOR gate 458 is the output (Out) of the divide-by-seven divider. Alternatively, other logic gates may be used rather than the NOR gate 458 that provide the same function (e.g., OR gate and inverter). As discussed supra, the divide-by-seven divider of FIG. 4 has approximately a 50% duty cycle.

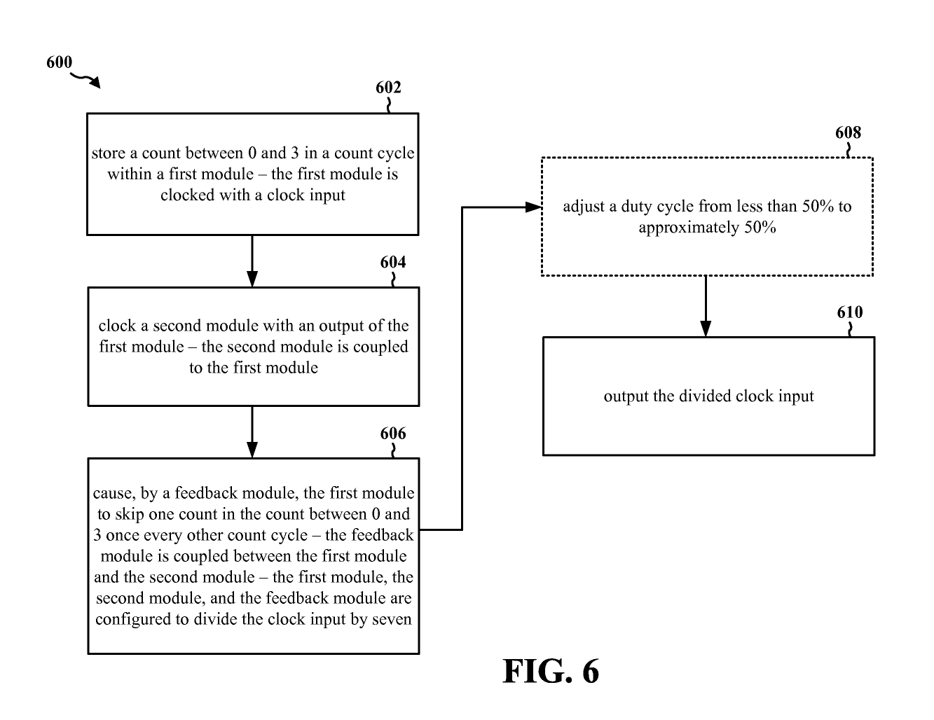

FIG. 6 is a flow chart 600 illustrating a method of operation of the exemplary divide-by-seven dividers. At step 602, the divide-by-seven divider stores a count between 0 and 3 in a count cycle within a first module. The first module is clocked with a clock input. At step 604, the divide-by-seven divider clocks a second module with an output of the first module. The second module is coupled to the first module. At step 606, the divide-by-seven divider causes, by a feedback module, the first module to skip one count in the count between 0 and 3 once every other count cycle. Specifically, the first module may be configured to store incrementally the count “00,” “10,” “11,” and “01” in a count cycle and to skip the count “01” every other count cycle based on input from the feedback module. The feedback module is coupled between the first module and the second module. The first module, the second module, and the feedback module are configured to divide the clock input by seven. At step 608, the divide-by-seven divider may adjust a duty cycle from less than 50% to approximately 50% (e.g., see the duty cycle adjustment module 460 of FIG. 4). At step 610, the divide-by-seven divider outputs the divided clock input.

In one configuration, a divide-by-seven divider apparatus includes means for storing a count between 0 and 3 in a count cycle within a first module. The first module is clocked with a clock input. The means for storing the count may be the first module 202/402. The divide-by-seven divider apparatus further includes means for clocking a second module with an output of the first module. The second module is coupled to the first module. The means for clocking the second module may be the first module 202/402, and second module 204/404, and a connection 238/438 between the first and second modules for clocking the second module 204/404 with an output of the first module 202/402. The divide-by-seven divider apparatus further includes means for causing, by a feedback module, the first module to skip one count in the count between 0 and 3 once every other count cycle. The feedback module is coupled between the first module and the second module. The first module, the second module, and the feedback module are configured to divide the clock input by seven. The means for causing the first module to skip one count may be the feedback module 206/406. The divide-by-seven divider apparatus may further include means for adjusting a duty cycle from less than 50% to approximately 50%. The means for adjusting may be the duty cycle adjustment module 460. The divide-by-seven divider apparatus further includes means for outputting the divided clock input.

Referring again to the divide-by-seven dividers of FIG. 2 and FIG. 4. In the exemplary divide-by-seven divider of FIG. 2, only two of the three DFFs are clocked by CLK, and in the exemplary divide-by-seven divider of FIG. 4, only two of the four DFFs are clocked by CLK. In the exemplary divide-by-seven dividers of FIG. 2 and FIG. 4, the third DFF 220/420 is running about four times slower than the first DFF 214/414 and the second DFF 216/416 (two clocked periods in the third DFF for every seven clocked periods in the first and second DFFs, which results in the third DFF running at approximately 29% speed of the first and second DFFs). The DFFs that are not clocked by CLK (e.g., the third and fourth DFFs) consume less power than the DFFs that are clocked by CLK (e.g., the first and second DFFs). Accordingly, power consumption is reduced in the exemplary divide-by-seven dividers. Further, in the exemplary divide-by-seven dividers of FIG. 2 and FIG. 4, there is no feedback path from the output of the third DFF (lowest speed) to the input of the first DFF (highest speed). Accordingly, logic gates that consume less power may be used in such feedback paths. As a result, the exemplary divide-by-seven dividers consume less power than existing divide-by-seven dividers.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects.” Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A divide-by-seven divider, comprising:
a first module clocked with a clock input; and
a second module coupled to the first module and clocked with an output of the first module, the first module and the second module being configured to divide the clock input by seven and to output the divided clock input.

2. The divide-by-seven divider of claim 1, wherein the first module is configured to store a count between 0 and 3 in a count cycle, the divide-by-seven divider further comprising a feedback module coupled between the first module and the second module and configured to cause the first module to skip one count in the count between 0 and 3 once every other count cycle.

3. The divide-by-seven divider of claim 2, wherein the first module is configured to store incrementally the count “00,” “10,” “11,” and “01” in a count cycle and to skip the count “01” every other count cycle based on input from the feedback module.

4. The divide-by-seven divider of claim 1, wherein the first module comprises a first stage and a second stage, the first stage having a first stage input and a first stage output, the second stage having a second stage input and a second stage output, the second stage output being coupled to the first stage input, the first stage output being coupled to the second stage input, and wherein the second module comprises a third stage, the third stage having a third stage input and a third stage output, the third stage being clocked by the second stage output, the third stage output being coupled to the third stage input.

5. The divide-by-seven divider of claim 4, further comprising a feedback module having a feedback module input and a feedback module output, the feedback module input being coupled to the third stage output and the second stage output, the feedback module output being coupled to the second stage input.

6. The divide-by-seven divider of claim 5, wherein the first stage comprises a first D flip-flop, the second stage comprises a second D flip-flop, and the third stage comprises a third D flip-flop.

7. The divide-by-seven divider of claim 5, wherein the first module further comprises a first inverter coupled to the first stage output, a NOR gate coupled between the first inverter and the second stage input, and a second inverter coupled between the second stage output and the first stage input.

8. The divide-by-seven divider of claim 7, wherein the second module further comprises a third inverter coupled between the third stage output and the third stage input.

9. The divide-by-seven divider of claim 8, wherein the feedback module comprises a NAND gate receiving inputs from the second stage output and the third stage output, and a fourth inverter coupled to an output of the NAND gate, an output of the fourth inverter being coupled to an input of the NOR gate.

10. The divide-by-seven divider of claim 4, wherein an output of the divide-by-seven divider is the third stage output and the divide-by-seven divider has approximately a 40% duty cycle.

11. The divide-by-seven divider of claim 4, further comprising a fourth stage having a fourth stage input and a fourth stage output, the first stage having a first stage second output, the fourth stage being clocked by the first stage second output, the third stage output being coupled to the fourth stage input, the third stage output and the fourth stage output being coupled to an output of the divide-by-seven divider.

12. The divide-by-seven divider of claim 11, wherein the third stage output and the fourth stage output are coupled to an input of a NOR gate, an output of the NOR gate being the output of the divide-by-seven divider, wherein the divide-by-seven divider has approximately a 50% duty cycle.

13. The divide-by-seven divider of claim 11, wherein the first stage second output is a value stored in a master latch of the first stage.

14. A method of operating a divide-by-seven divider, comprising:
storing a count between 0 and 3 in a count cycle within a first module, the first module being clocked with a clock input;
clocking a second module with an output of the first module, the second module being coupled to the first module;
causing, by a feedback module, the first module to skip one count in the count between 0 and 3 once every other count cycle, the feedback module being coupled between the first module and the second module, the first module, the second module, and the feedback module being configured to divide the clock input by seven; and
outputting the divided clock input.

15. The method of claim 14, wherein the first module is configured to store incrementally the count “00,” “10,” “11,” and “01” in a count cycle and to skip the count “01” every other count cycle based on input from the feedback module.

16. The method of claim 14, wherein the first module comprises a first stage and a second stage, the first stage having a first stage input and a first stage output, the second stage having a second stage input and a second stage output, the second stage output being coupled to the first stage input, the first stage output being coupled to the second stage input, and wherein the second module comprises a third stage, the third stage having a third stage input and a third stage output, the third stage being clocked by the second stage output, the third stage output being coupled to the third stage input.

17. The method of claim 16, wherein the feedback module has a feedback module input and a feedback module output, the feedback module input being coupled to the third stage output and the second stage output, the feedback module output being coupled to the second stage input.

18. The method of claim 16, wherein an output of the divide-by-seven divider is the third stage output and the divide-by-seven divider has approximately a 40% duty cycle.

19. The method of claim 16, further comprising adjusting a duty cycle from less than 50% to approximately 50% by a fourth stage, the fourth stage having a fourth stage input and a fourth stage output, the first stage having a first stage second output, the fourth stage being clocked by the first stage second output, the third stage output being coupled to the fourth stage input, the third stage output and the fourth stage output being coupled to an output of the divide-by-seven divider.

20. A divide-by-seven divider apparatus, comprising:
means for storing a count between 0 and 3 in a count cycle within a first module, the first module being clocked with a clock input;
means for clocking a second module with an output of the first module, the second module being coupled to the first module;
means for causing, by a feedback module, the first module to skip one count in the count between 0 and 3 once every other count cycle, the feedback module being coupled between the first module and the second module, the first module, the second module, and the feedback module being configured to divide the clock input by seven; and
means for outputting the divided clock input.
